(19) United States
(12) Patent Application Publication
(10) Pub. No.: US 2018/0331062 A1
(43) Pub. Date: Nov. 15, 2018

(54) ELECTRICAL COMPONENT WITH THIN SOLDER RESIST LAYER AND METHOD FOR THE PRODUCTION THEREOF

(71) Applicant: SnapTrack, Inc., San Diego, CA (US)

(72) Inventor: Alexander SCHMAJEW, München (DE)

(21) Appl. No.: 15/776,019

(22) PCT Filed: Sep. 6, 2016
(86) PCT No.: PCT/EP2016/070973

§ 371 Date: May 14, 2018

(30) Foreign Application Priority Data
Nov. 27, 2015 (DE) 10 2015 120 647.1

(51) Int. Cl. H01L 23/00; H01L 23/498; H01L 23/31; H01L 21/56; H01L 21/48

(52) U.S. Cl. CPC H01L 24/16; H01L 2224/1148; H01L 23/3121; H01L 23/49838; H01L 24/81; H01L 21/565; H01L 21/4853; H01L 2224/81815; H01L 2224/16227; H01L 2224/81192; H01L 2924/3841; H01L 2224/1132; H01L 24/11; H01L 2224/0401; H01L 24/05; H01L 2224/10175; H01L 23/49811

(57) ABSTRACT

An electrical device and a method for the manufacture of an electrical device are specified. The device has a carrier with an upper side and a metallized contact surface arranged on it as well as a solder mask layer which covers a part of the upper side but not the contact surface. The solder mask layer has a thickness of 200 nm or less, thereby facilitating subsequent process steps for encapsulating the device.

The invention relates to electrical devices, for example, devices suitable for surface mounting (SMT=surface-mount technology) or devices with electrical components installed with SMT technology as well as a process for their production.

In modern SMT technology, solderable bumps are used for electrical interconnection and mechanical connection between a support, for example, a printed circuit board, and an electrical component, such as discrete components or modules. The bump material is applied in a single step, for example, by stencil printing, and then heated (reflow process). The usual solder materials, such as solder paste, may contain fluxes which during heating attack the surface of the carrier. There is also a danger of the solder paste reaching solderable surfaces that should remain free of solder in order to prevent electrical short circuits, for example.

To avoid these risks, sensitive areas of the surface can be covered by a protective layer, such as a solder mask layer.

The problem with using a solder mask layer is the increased expense in the manufacture of the components, since the solder mask layer has to be structured in a way that in an optimal case all sensitive areas are covered by a protective layer but not those areas which really do have to be provided with solder. It is also the case that electrical devices should have smaller and smaller dimensions. Conventional solder mask layers, when compared with the current dimensions of bump connections, are already so thick that further problems could occur during subsequent steps for encapsulating the devices. Many devices are encapsulated and mechanically stabilized by overmolding the upper side with a molding compound which is then cured. The problem here is that the molding compound no longer fills the intermediate space between the component and the carrier with sufficient reliability when the intermediate space is too low due to the thickness of the solder mask layer.

For this reason the task emerged of providing an electrical device in which the solder wets only the desired areas and, following a heating process, may form a ball or half-ball without spreading to areas adjacent to the contact surface. A protective layer should have good adhesion to the surface of the carrier, withstand high temperatures without degradation, for example, above 250° C. in a reflow process, be mechanically stable, chemically neutral and not conduct electrical current. In particular, the protective layer should be as thin as possible in order that a molding compound to be applied later should if at all possible fill the intermediate spaces as well. Furthermore, a process was wanted for producing such a component.

These desires were met by the electrical device and by the method for producing an electrical device according to the independent claims. Dependent claims specify advantageous embodiments.

The electrical device comprises a carrier with an upper side, a metallized contact area on the upper side, and a solder mask layer which covers a part of the upper side but not the contact surface. The solder mask layer has a thickness of 200 nm or less.

The solder mask layer thus has a thickness whereby, even with the currently small dimensions of bump joints and the resultant close separations between carrier and electrical component, intermediate spaces can still be reliably filled.

Here the carrier can be a printed circuit board or a chip. The metallized contact surface is preferably a solderable metallized surface, which is intended to be connected via a bump joint. Here the metallized contact surface can in particular be a so-called under-bump metallization and on the other hand have a multi-layered structure.

It is possible for the solder mask layer to have a thickness between 30 nm and 80 nm.

It is also possible for the device to have a bump ball on the metallized contact surface.

The bump ball on the metallized contact surface can then consist of a solder material which was applied by a stencil printing method to the area of the metallized contact surface. During a subsequent heating process the material melts and due to surface tension forms a shape with relatively small surface area, a ball. The metallized contact surface can be connected to a further metallization on the upper side of the carrier, for example, a signal line in the form of a stripline. In addition to this metallization, a further metallization may be disposed on the upper side of the carrier. The two further metallizations in addition to the contact surface on the upper side of the carrier are preferably covered by the solder mask layer. The solder mask layer can be poorly wettable by solder. In this case, during heating the solder material independently centers itself away from the region of poor wettability toward the metallized contact surface which is free of the material of the solder mask layer.

The solder material and/or its flux here do not attack sensitive areas on the upper side of the carrier. Even if electrically conductive solder material is left in an area adjacent to the contact surface, the solder mask layer acts as an electrical insulator and signal lines are not short-circuited.

It is also possible for the device to additionally include an electrical component. This electrical component may have a contact surface on the underside. The device will then in addition include a bump joint that connects the two contact surfaces.

The carrier and the electrical component, for example, a discrete device or a module, are connected to each other electrically conductively and mechanically via the bump joint.

The carrier can, of course, have a plurality of further metallized contact surfaces on its surface. The device may further comprise a plurality of different electrical components that are joined to and connected with the metallized contact surfaces of the carrier via bump joints, wherein each of the electrical components, in turn, has a metallized contact surface on its underside.

The single electrical component or the plurality of electrical components may also in each case have a solder mask layer on the underside. The solder mask layers of the electrical components can here be conventional protective layers. They can also be solder mask layers of the type of the present protective layer.

In particular, when two protective layers are arranged between a component and the carrier, the advantage of the low thicknesses of the present protective layers is brought to bear since the effect on the height of the free intermediate space is doubled.

Accordingly, it is possible for the device to include a molding compound that covers at least parts of the upper side of the carrier and at least one electrical component.

It is then in particular advantageous when the molding compound fills also the intermediate space between the electrical component and the carrier or between all of the electrical components and the carrier.

Should sensitive device structures be arranged on the upper side of the carrier or on the underside of an electrical component, for example, MEMS device structures such as SAW structures (SAW=surface acoustic wave), BAW structures (BAW=bulk acoustic wave) and so on, it is then preferable for a hermetically sealed volume between the component and the carrier to be left free of the material of the molding compound. To do so, an additional frame structure may be arranged between the component and the carrier that laterally encloses the hollow space. The hollow space is then formed by the surfaces of the carrier and of the component and by the frame.

It is possible for the device to include a first signal line connected to the contact surface and located on the upper side of the carrier. The device has in addition a second signal line on the upper side of the carrier. The two signal lines are at least partially covered by the solder mask layer. The electrical resistance between the two signal lines is 100 MΩ or more.

Here the lateral distance between the signal lines can be on the order of 180 μm. The solder mask layer has a thickness which, depending on the material of the layer, is selected such that a minimum resistance of 100 MΩ is ensured.

It is possible for the solder mask layer to include silicon as its main constituent or to be made entirely of silicon.

It has been found that thin solder mask layers of this kind made of silicon or of another material with similar electrical insulation properties are surprisingly easy to manufacture when the method described below is used. In principle, any material with sufficiently low wettability by solder and sufficiently low electrical conductivity can be used for the solder mask layer. Here it is preferred that the materials can be deposited by the usual processing methods, such as those of the semi-conductor industry, and that they adhere well to the upper side of the carrier.

The solder mask layer can also include germanium as its main constituent or be made entirely of germanium.

The solder mask layer can in principle be composed of any dielectric material. However, those materials which can be deposited relatively easily as an appropriately thin layer are preferred. These in particular include materials which can be applied to surfaces by reactive or non-reactive PVD processes, such as oxides and nitrides of silicon, titanium, aluminum, or chrome.

It is possible for the device to have device structures on the upper side of the carrier or on the underside of at least one electrical component. The device structures can have a height of 40 μm or more. The device structures may be SAW device structures, BAW device structures, MEMS device structures (MEMS=micro-electro-mechanical system) or GBAW device structures (GBAW=guided bulk acoustic wave) or similar component structures. The carrier on its upper side or the electrical component on its underside thus has a complex topology which can only be poorly covered by conventional solder mask layers or not at all.

The other solderable metal surfaces which are to be protected by the solder mask layer can comprise nickel, copper, alloys of these two elements or alloys with these two elements, gold, silver, palladium, rhodium, tin and/or zinc.

In principle the number of contact surfaces, of electrical components and of contact surfaces of the electrical components is not limited, and especially in the case of electrical components with integrated circuits, the electrical component and the carrier can be joined and connected via many hundreds of bump joints.

The carrier is not limited to printed circuit boards. The carrier itself can in turn be an electrical component that is arranged on and connected to a further carrier or a further electrical component, and so on.

A method for producing such an electrical device comprises these steps:

Provision of a carrier with an upper side and a metallized contact surface on the upper side,

Arranging a lacquer layer on the upper side and structuring the layer of varnish in such a way that material of the lacquer layer remains on the contact surface and the areas of the surface without any contact surface are free of the material of the lacquer layer,

Depositing a solder mask layer on the upper side of the carrier,

Removing the remaining material of the lacquer layer together with the material of the solder mask layer over the contact surface.

Here the lacquer layer can comprise a material which is usual for photolithographic processes and, for example, be applied by spin coating. Once the material of the solder mask layer has been applied to the remaining areas of the structured lacquer layer and to the now exposed surfaces of the carrier, the material of the photoresist can be removed by stripping. The structured solder mask layer is thereby generated in the form of the desired solder mask without additional structuring of the solder mask layer. This method reduces the complexity of the overall process and the costs of manufacturing the device in comparison with conventional methods.

It is possible for the solder mask layer to be given a thickness of 200 nm or less.

It is possible in particular for the solder mask layer to be given a thickness between 20 nm and 80 nm.

It is possible for the solder mask layer formed during the process to have germanium as its main constituent or to consist entirely of silicon or germanium.

Other materials with similar electrical properties and a similar wettability are also possible.

It is possible for the electrical device to have a further solderable metal surface on the upper side and for the solder mask layer to be deposited directly on the further solderable metal surface.

Here the further solderable metal surface can be a metal surface of a signal line or a capacitive, inductive or resistive element implemented on the upper side of the carrier.

It is possible for the material of the solder mask layer to be applied by means of PVD (PVD=physical vapor deposition) or by means of CVD (CVD=chemical vapor deposition).

It is also possible for the method to comprise the steps of arranging solder paste, at least on the contact surface; arranging on the upper side of the carrier an electrical component with a contact surface on its underside; reflow soldering the device; and connecting the two contact surfaces by means of a bump joint.

It is also possible for the method to include the step of enveloping the electrical device with a molding compound. Here the molding compound also fills the area between the component and the carrier.

The lacquer, which is structured prior to application of the material of the solder mask layer in order to receive the solder mask layer, can have a thickness between 0.5 μm and 10 μm, for example, between 2 μm and 4 μm, and be a standard lacquer used in semiconductor manufacturing. The lacquer can not only be spin-coated but also be sprayed onto the upper side of the carrier.

The main ideas and principles of operation underlying the device and manufacturing method and also schematic examples are outlined in the figures.

Shown are:

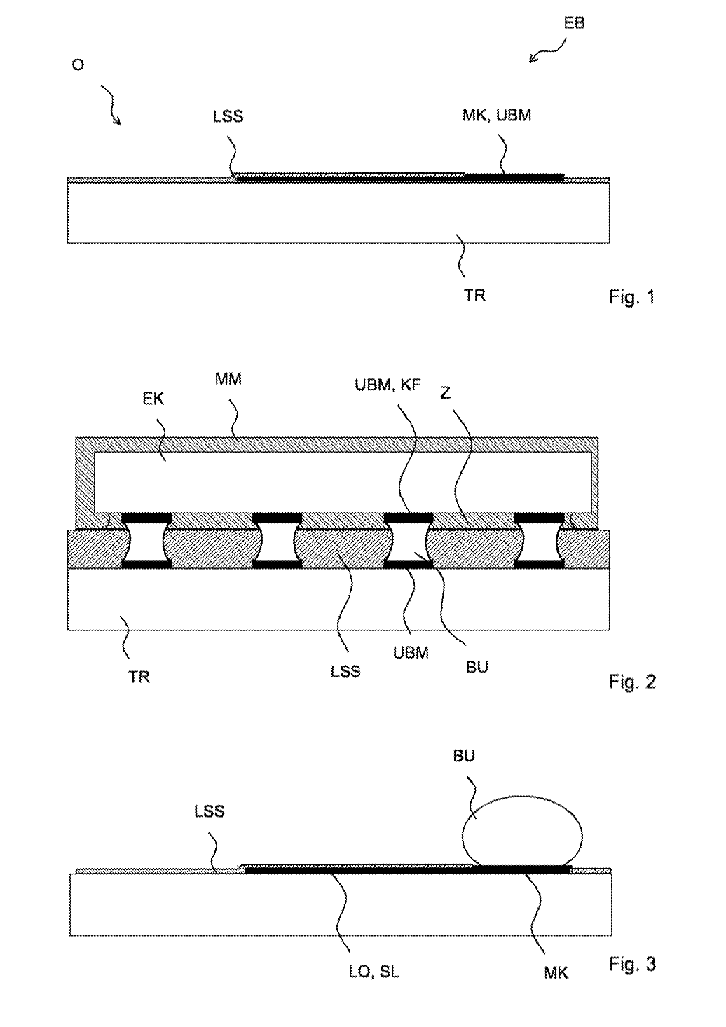

FIG. 1: a cross-section through an electrical device,

FIG. 2: a cross-section through a device with further encapsulation,

FIG. 3: a cross-section through a device with a bump ball on the contact surface,

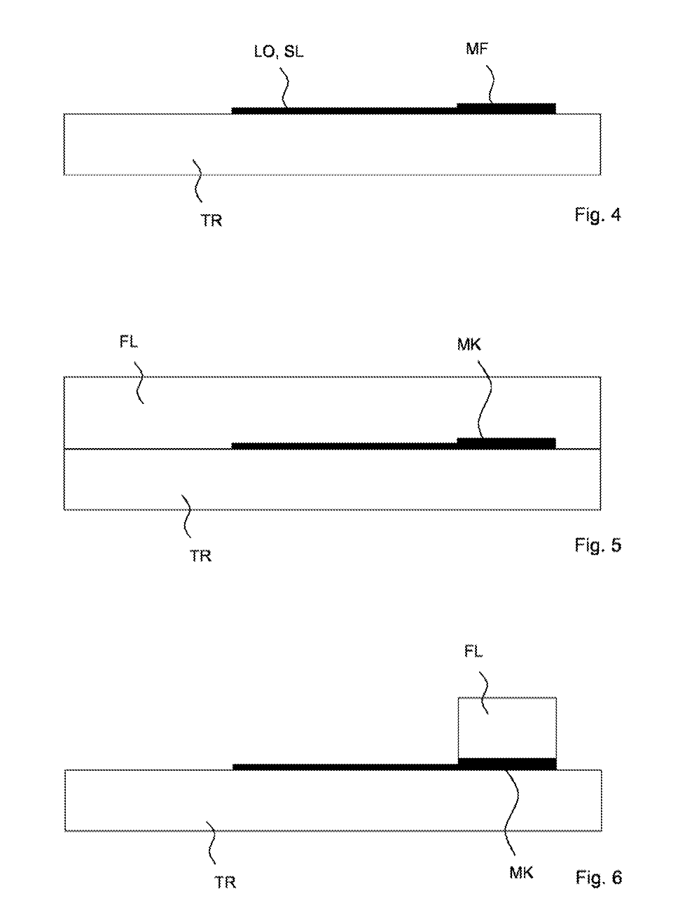

FIG. 4: a first intermediate step in the manufacture of a device,

FIG. 5: a second intermediate step,

FIG. 6: a third intermediate step,

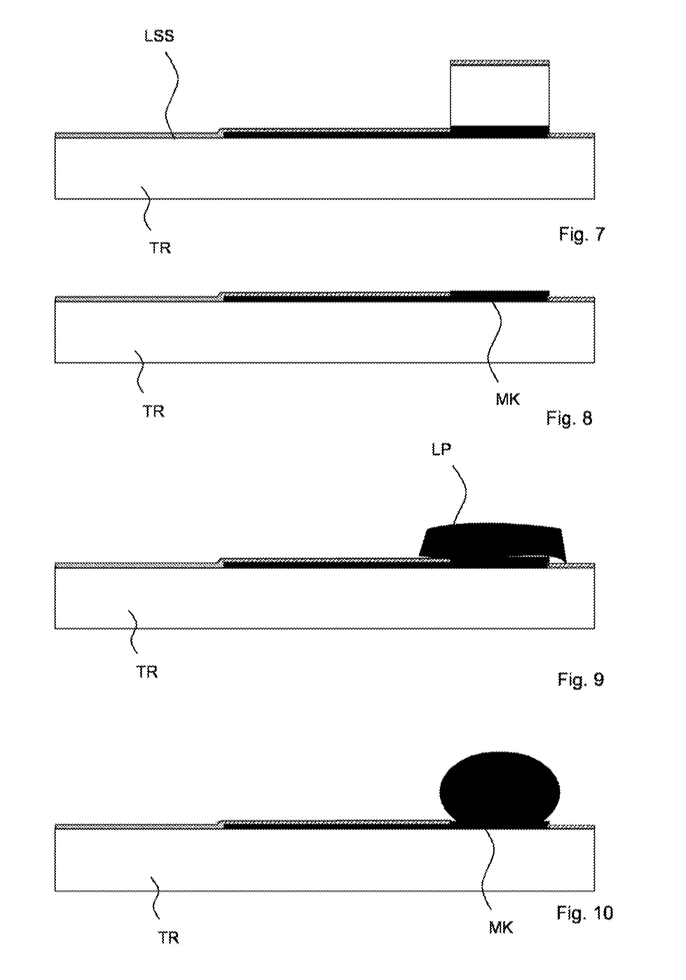

FIG. 7: a fourth intermediate step,

FIG. 8: a first intermediate result in the manufacture of a complex electrical device,

FIG. 9: a further intermediate step,

FIG. 10: a further intermediate step after heating,

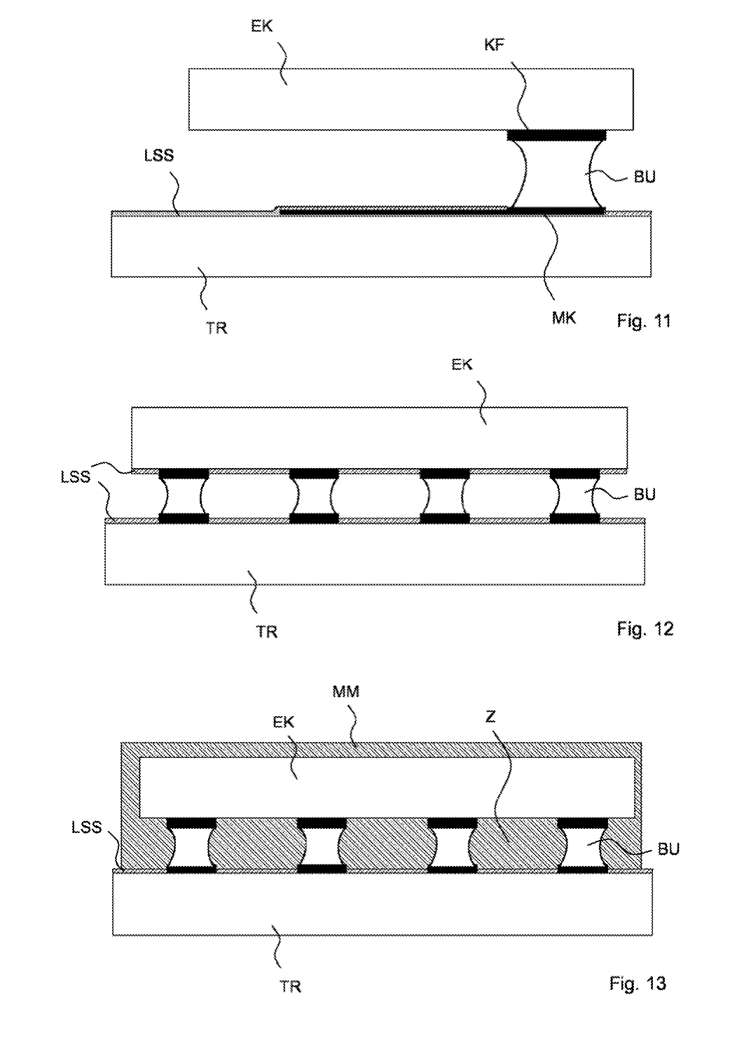

FIG. 11: a cross-section through a simple embodiment of the device,

FIG. 12: a cross-section through an alternative embodiment,

FIG. 13: a cross-section through a device with a thin solder mask layer and with a molding compound which fills the intermediate spaces between the electrical component and the carrier.

FIG. 1 shows a cross-section through a simple embodiment of the electrical device EB. The electrical device EB has a carrier TR, on which a metallized contact surface MK is structured. The metallized contact surface MK is intended to be connected to an electrical component via a bump joint. On the upper side O of the carrier TR, a solder mask layer LSS is arranged which covers those areas of the upper side of the carrier TR which should not come into direct contact with solder material.

Here the metallized contact surface may be a so-called under-bump metallization, UBM, and have a readily wettable surface.

FIG. 2 shows a cross-section through a form of an electrical device with a relatively thick solder mask layer LSS. The solder mask layer LSS reliably protects sensitive areas on the upper side of the carrier TR from being wetted with solder, provided the upper side of the carrier TR is sufficiently flat. If the device is to be encapsulated by a molding compound MM, a thick solder mask layer will, however, be an obstacle to filling the intermediate space Z between the carrier TR and the underside of the electric component EK, which is joined and connected to the carrier TR via the bump joints BU.

FIG. 3 shows a cross-section through an electrical device in which a bump ball BU has already formed on the metallized contact surface MK. Due to the surface tension of the solder, a ball-like shape forms during the course of the reflow process. The thickness of the solder mask layer LSS is very small compared to the height of the bump ball or the subsequent bump joint connection to an electrical component.

A material with a solderable surface LO, for example, a signal line SL, is arranged on the surface of the carrier and can include nickel, copper, gold or silver. Without a solder mask layer LSS, there is a danger that the material of the bump ball BU does not accumulate on the contact surface MK, but attacks the signal line and possibly shorts out the signal line and a further circuit element on the upper side of the carrier.

FIG. 4 shows a cross-section through a first intermediate result in the manufacture of the electrical device. The contact surface MK and the signal conductor SL as examples of elements to be protected are arranged on the upper side of the carrier TR.

FIG. 5 shows a cross-section through a further intermediate step, in which the entire surface, including the areas to be protected and the areas to be wetted subsequently by the solder, is covered by a photoresist FL.

FIG. 6 shows a cross-section through a further intermediate step, in which the photoresist FL is so structured that only the areas MK, which should later on remain free of the material of the solder mask layer, remain covered by the material of the photoresist FL.

To this end photoresist can be selectively exposed and developed.

FIG. 7 shows the result of a further intermediate step, in which the entire upper side of the previous electrical device is covered by the material of the subsequent solder mask layer LSS. The sensitive areas are directly covered by the material of the solder mask layer LSS. Where solder is subsequently to be disposed is where the remaining photoresist FL is found between the material of the solder mask layer LSS and the contact surface.

FIG. 8 correspondingly shows the result of a further process step, wherein the remaining remnants of photoresist FL have been removed together with the segments of the material of the solder mask layer LSS deposited on them, so that the surface to be wetted lies exposed without being covered by the solder mask layer.

FIG. 9 shows the result of a further step, namely, of applying a solder paste LP to areas which mainly correspond to the areas of the contact surfaces MK. Due to the precise defined edges of the solder mask layer LSS, lateral positioning need not be overly precise during application of the solder paste LP as long as a substantial area of the contact surface MK is covered by the solder paste LP.

FIG. 10 shows the result of a further intermediate step in the manufacture of the electrical device, wherein following heating the material of the solder paste LP has concentrated into a ball at the position of the contact surface MK.

FIG. 11 shows a cross-section through an electrical device wherein the contact surface MK on the underside of the electric component EK and the contact surface MK on the upper side of the carrier TR are connected via a bump joint which developed from the bump ball in FIG. 10.

FIG. 12 shows a cross-section through a further embodiment in which the electrical component EK and the carrier TR are joined and connected via a plurality of bump joints BU. In addition to the solder mask layer LSS on the upper side of the carrier TR a solder mask layer LSS—preferably equally thin—can be arranged on the underside of the electric component EK.

Finally, FIG. 13 shows a cross-section through an encapsulated electric device in which a molding compound MM encloses the electrical component on the upper side of the carrier TR and fills the intermediate spaces Z between the electrical component EK and the carrier TR.

### LIST OF REFERENCE SIGNS

BU: Bump joint
EB: Electrical device
EK: Electrical component
FL: Photoresist
KF: Contact surface
LO: Solderable surface
LP: Solder paste
LSS: Solder mask layer
MK: Metallized contact surface
MM: Molding compound
O: Upper side of the carrier
SL: Signal line
TR: Carrier
UBM: Under-bump metallization
Z: Intermediate space

1. An electrical device (EB) comprising
a carrier (TR) with an upper side (O),
a metallized contact surface (MK) on the upper side (O),
a solder mask layer (LSS) that covers part of the upper side (O) but not the contact surface (MF),
wherein
the solder mask layer (LSS) has a thickness of 200 nm or less.

2. Device according to the preceding claim, wherein the solder mask layer (LSS) has a thickness between 30 nm and 80 nm.

3. Device according to the preceding claim, further comprising a bump ball (BU) on the metallized contact surface (MK).

4. Device according to any one of the preceding claims, further comprising an electrical component (EK) with a contact surface (KF) on the underside and a bump joint (BU) that connects the two contact surfaces (MK, KF).

5. Device according to the preceding claim, further comprising a molding compound that covers at least parts of the upper side of the carrier (TR) and the electrical component (EK).

6. Device according to the preceding claim, wherein the molding compound also fills the intermediate space (Z) between the electrical component (EK) and the carrier (TR).

7. The component according to any of the preceding claims, furthermore comprising
a first signal line (SL) on the upper side (O) of the carrier (TR) and interconnected with the contact surface (MK),
a second signal line (SL) on the upper side (O) of the carrier (TR), wherein
both signal lines (SL) are at least partially covered by the solder mask layer (LSS), and
the electrical resistance between the two signal lines (SL) is 100 MΩ or more.

8. Device according to any one of the preceding claims, wherein the solder mask layer (LSS) has silicon as its main constituent or is made of silicon.

9. Device according to any one of the preceding claims, wherein device structures are arranged on the upper side (O) of the carrier (TR) which have heights of 40 μm or more.

10. A method for producing an electric device (EB), comprising the steps
Provision of a carrier (TR) with an upper side (O) and a metallized contact surface (MK) on the upper side (O),
Arranging a lacquer layer (FL) on the upper side (O) and structuring the lacquer layer (FL) in such a way that material of the lacquer layer (FL) remains on the contact surface (MK) and the areas of the surface (O) with no contact surface (MK) are free of the material of the lacquer layer (FL),
Depositing a solder mask layer (LSS) on the upper side (O) of the carrier (TR),
Removing the remaining material of the lacquer layer (FL) together with the material of the solder mask layer (LSS) over the contact surface (MK).

11. Method according to the preceding claim, wherein the solder mask layer (LSS) is given a thickness of 200 nm or less.

12. Device according to the preceding claim, wherein the solder mask layer (LSS) is given a thickness between 20 nm and 80 nm.

13. Method according to any one of the three preceding claims, wherein the solder mask layer (LSS) includes silicon as its main constituent or is made of silicon.

14. Method according to any one of the four preceding claims, wherein the electrical device (EB) has a further solderable metal surface (LO) on the upper side and the solder mask layer (LSS) is directly deposited on the further solderable metal surface (LO).

15. Method according to any one of the five preceding claims, wherein the solder mask layer (LSS) is applied by means of PVD or CVD.

16. Method according to any one of the five preceding claims, further comprising the steps
Arranging solder paste (LP), at least on the contact surface (MK),
Arranging an electrical component (EK) with a contact surface (MK, KF) on its underside on the upper side (O) of the carrier (TR),
Reflow soldering the device (EB) and connecting the two contact surfaces (MK, KF) by means of a bump joint (BU).

17. Method according to the preceding claim, further comprising the step
Encapsulating the electrical component (EK) with a molding compound (MM),
wherein
the molding compound (MM) also fills the area between the component (EK) and the carrier (TR).
